(19) United States
(12) Patent Application Publication
(10) Pub. No.: US 2023/0178365 A1
(43) Pub. Date: Jun. 8, 2023

(54) NH RADICAL THERMAL NITRIDATION TO FORM METAL SILICON NITRIDE FILMS

(71) Applicant: Applied Materials, Inc., Santa Clara, CA (US)

(72) Inventors: Wei Liu, San Jose, CA (US); Fredrick Fishburn, Aptos, CA (US); Hailing Liu, Union City, CA (US)

(73) Assignee: Applied Materials, Inc., Santa Clara, CA (US)

(21) Appl. No.: 17/994,592

(22) Filed: Nov. 28, 2022

Related U.S. Application Data
(60) Provisional application No. 63/285,595, filed on Dec. 3, 2021.

(51) Int. Cl. H01L 21/02

(52) U.S. Cl. CPC H01L 21/02247; H01L 21/02153; H01L 21/0217; H01L 21/02252

(57) ABSTRACT

Semiconductor devices and methods of forming semiconductor devices are described. A method of forming metal silicon nitride films is disclosed. Some embodiments of the disclosure provide a process using ammonia plasma for treating a metal silicide or metal film to form a metal silicon nitride film. The ammonia plasma treatment generates NH* radicals that diffuse through the metal silicide to form a metal silicon nitride film that is substantially free of silicon nitride (SiN). The metal silicon nitride films have improved resistance relative to films deposited by thermal processes or plasma processes with a nitrogen plasma exposure.

### CROSS-REFERENCE TO RELATED APPLICATIONS

This application claims priority to U.S. Provisional Application No. 63/285,595, filed Dec. 3, 2021, the entire disclosure of which is hereby incorporated by reference herein.

### TECHNICAL FIELD

Embodiments of the present disclosure pertain to the field of electronic devices and electronic device manufacturing. More particularly, embodiments of the disclosure provide electronic devices that include a metal silicon nitride film that is substantially free of silicon nitride (SiN) and methods of forming the same.

### BACKGROUND

Integrated circuits have evolved into complex devices that can include millions of transistors, capacitors, and resistors on a single chip. In the course of integrated circuit evolution, functional density (i.e., the number of interconnected devices per chip area) has generally increased while geometry size (i.e., the smallest component (or line) that can be created using a fabrication process) has decreased.

The integrated circuit density on semiconductor substrates has dramatically increased, and the minimum feature sizes, such as the field effect transistor (FET) channel lengths and the word line widths on dynamic random-access memory (DRAM) have dramatically decreased.

One difficulty with DRAM is that the bit line contact is a metal to silicon small contact that is formed early in the process flow. The bit line contact must withstand high temperatures without agglomeration of the silicide. Current methods of manufacture use tungsten nitride (WN) or nitrogen (N₂) and rapid thermal processing (RTP) to react the nitrogen (N₂) with the titanium silicide (TiSi) to form titanium silicon nitride (TiSiN). Tungsten nitride (WN), however, is difficult to deposit with high step coverage, and the nitrogen (N₂) reacts with the silicon (Si) directly and forms silicon nitride (SiN) on the substrate, leading to high contact resistance.

Therefore, there is a need in the art for methods of forming bit line contacts where a minimum of silicon nitride (SiN) is formed during formation of titanium silicon nitride (TiSiN).

### SUMMARY

One or more embodiments of the disclosure are directed to a method of forming a semiconductor device. In one or more embodiments, the method comprises: exposing a metal silicide film to a plasma comprising ammonia (NH₃) at a temperature in a range of from 450° C. to 1000° C. to form NH radicals that diffuse through the metal silicide film and form a metal silicon nitride film that is substantially free of silicon nitride (SiN).

Additional embodiments of the disclosure are directed to a method of forming a semiconductor device. In one or more embodiments, the method comprises: exposing a titanium film to a plasma comprising ammonia (NH₃) at a temperature in a range of from 450° C. to 1000° C. to form NH radicals that diffuse through the titanium film and form a titanium silicon nitride (TiSiN) film that is substantially free of silicon nitride (SiN).

Further embodiments of the disclosure are directed to a non-transitory computer readable medium including instructions, that, when executed by a controller of a processing chamber, causes the processing chamber to perform the operations of: expose a metal silicide film to a plasma comprising ammonia (NH₃) at a temperature in a range of from 450° C. to 1000° C. to form NH radicals that diffuse through the metal silicide film and form a metal silicon nitride film that is substantially free of silicon nitride (SiN).

### BRIEF DESCRIPTION OF THE DRAWING

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a process flow diagram for the formation of a film according to one or more embodiment of the disclosure; and

FIGS. 2A-2D illustrate cross-section views of an exemplary substrate during the formation of a film according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used in this specification and the appended claims, the terms “precursor,” “reactant,” “reactive gas” and the like are used interchangeably to refer to any gaseous species that can react with the substrate surface.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor.

Embodiments of the present disclosure relate to methods for forming metal silicon nitride films, e.g., titanium silicon nitride (TiSiN), that are substantially free of silicon nitride (SiN). The metal silicon nitride films may be formed from films of titanium (Ti) or titanium/titanium nitride (Ti/TiN) on silicon (Si) or films of titanium silicide (TiSi). The metal silicon nitride films may be formed using a thermal plasma process.

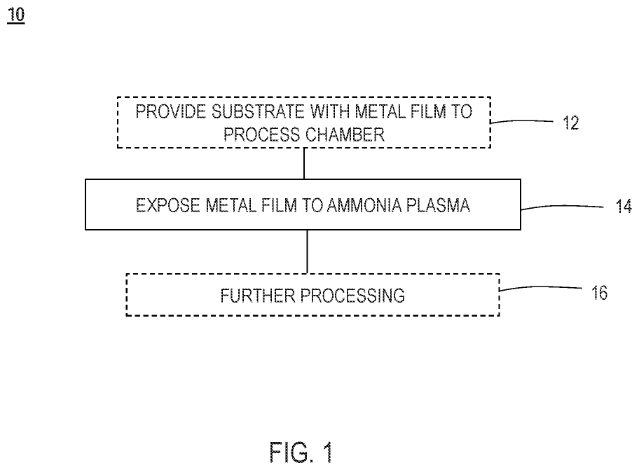

FIG. 1 depicts a generalized method 10 for forming a metal silicon nitride film on a substrate in accordance with one or more embodiment of the disclosure. The method 10 generally begins at operation 12, where a substrate having a metal film thereon is provided and placed into a processing chamber. As used in this specification and the appended claims, the term “provided” means that the substrate or substrate surface is made available for processing (e.g., positioned in a processing chamber). At operation 14, substrate having the metal film thereon is exposed to an ammonia plasma to form a metal silicon nitride film. At operation 16, the method 10 moves to an optional post-processing operation.

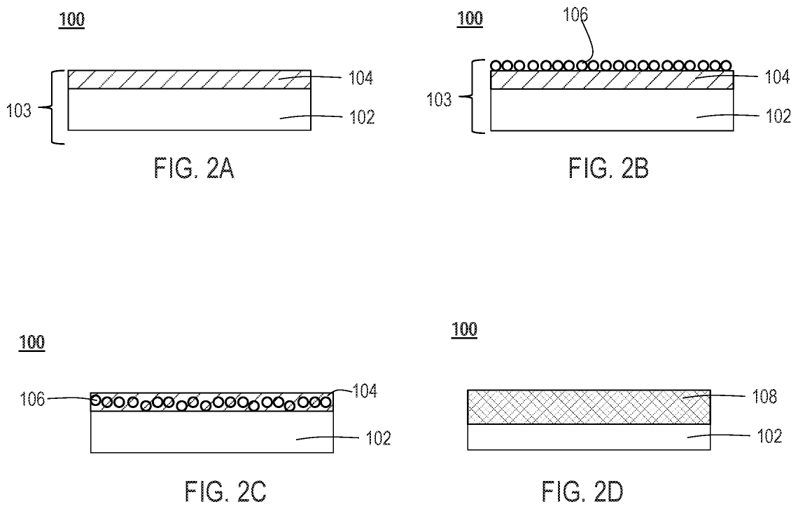

FIGS. 2A to 2D illustrate cross-section views of an exemplary device 100 during the formation of a metal silicon nitride film according to one or more embodiments of the disclosure. With reference to FIG. 1 and FIG. 2A, at operation 12, a substrate 102 having a metal film 104 thereon is provided. The substrate 102 may comprise any suitable material known to the skilled artisan. In some embodiments, the substrate 102 comprises silicon (Si) or silicon germanium (SiGe).

The metal film 104 may comprise any suitable metal known to the skilled artisan. In one or more embodiments, the metal film 104 comprises a metal selected from titanium (Ti), cobalt (Co), molybdenum (Mo), ruthenium (Ru), tungsten (W), nickel (Ni), and the like. It will be appreciated by one of skill in the art that when the metal film 104 forms on the substrate 102, a metal silicide 103 may result. In one or more embodiments, the metal silicide 103 comprises titanium silicide (TiSi), cobalt silicide (CoSi), molybdenum silicide (MoSi), ruthenium silicide (RuSi), tungsten silicide (WSi), nickel silicide (NiSi), and the like.

In one or more embodiments, the metal film 104 comprises titanium (Ti) or titanium/titanium nitride (Ti/TiN) on a substrate 102 comprising silicon. In some embodiments, therefore, the metal silicide 103 is titanium silicide (TiSi).

The metal film 104 or the metal silicide 103 may have any suitable thickness. In one or more embodiments, the metal film 104 or the metal silicide 103 has a thickness in a range of from 0.5 nm to 15 nm, or in a range of from 1 nm to 10 nm, or in a range of from 2 nm to 6 nm.

The metal film 104 may be formed by any suitable deposition process known to the skilled artisan. In one or more embodiments, the deposition process includes atomic layer deposition (ALD), physical vapor deposition (PVD), chemical vapor deposition (CVD), or the like.

The process of forming the metal film 104 may begin by exposing the substrate to a precursor for a period of time. In some embodiments, the precursor is supplied without the use of a plasma.

A “pulse” or “dose” as used herein is intended to refer to a quantity of a source gas that is intermittently or non-continuously introduced into the process chamber. The quantity of a particular compound within each pulse may vary over time, depending on the duration of the pulse. A particular process gas may include a single compound or a mixture/combination of two or more compounds, for example, the process gases described below.

The precursor may be any suitable compound to adsorb a layer of reactive species on the substrate surface for later reaction. The reactive species may also be referred to by the identity of the precursor. For example, exposing the substrate to a titanium precursor would form a reactive species referred to as a titanium species.

In some embodiments, the precursor includes a metal selected from one or more of titanium (Ti), cobalt (Co), molybdenum (Mo), ruthenium (Ru), tungsten (W), nickel (Ni), and the like. Accordingly, in some embodiments, the metal film 104 comprises one or more of titanium (Ti), cobalt (Co), molybdenum (Mo), ruthenium (Ru), tungsten (W), nickel (Ni), and the like.

In some embodiments, the metal film 104 comprises or consists essentially of titanium (Ti) and titanium nitride (TiN). In some embodiments, the metal film 104 comprises or consists essentially of titanium (Ti).

Referring to FIG. 1 and FIG. 2B, at operation 14, the device 100 is exposed to and treated with a plasma. In one or more embodiments, the plasma is an ammonia (NH₃) plasma. The ammonia plasma may be generated from a plasma gas to form radicals. In one or more embodiments, the ammonia plasma forms NH* radicals 106 on the surface of the metal film 104 or the metal silicide 103. In one or more embodiments, the plasma comprises NH* radicals. In some embodiments, the plasma gas comprises ammonia gas (NH₃). In some embodiments, the plasma gas further comprises an inert gas. The inert gas may comprise any suitable inert gas including, but not limited to argon (Ar), helium (He), and xenon (Xe). In some embodiments, the inert is flowed continuously while the ammonia gas is pulsed. In one or more embodiments, the ammonia plasma is diluted with an inert gas to generate maximum NH* radicals. In one or more embodiments, the ratio of ammonia to inert gas (i.e., NH₃:Ar, NH₃:He, NH₃:Xe) is in a range of from 1:10,000 to 10:1, or in a range of from 1:100 to 1:5 or is a ratio of 1:10.

In some embodiments, the ammonia plasma gas is flowed into the processing chamber and then ignited to form a direct plasma. In some embodiments, the ammonia plasma gas is ignited outside of the processing chamber to form a remote plasma.

In some embodiments, the ammonia plasma is an inductively coupled plasma (ICP). In some embodiments, the ammonia plasma is a conductively coupled plasma (CCP). In some embodiments, the ammonia plasma is a microwave plasma. In some embodiments, the ammonia plasma is generated by passing the ammonia plasma gas over a hot wire.

With reference to FIGS. 2C and 2D, exposing the metal film 104 or the metal silicide 103 to a plasma comprising ammonia (NH₃) at a temperature in a range of from 450° C. to 1000° C. forms NH* radicals 106 that diffuse through the metal film 104 (or the metal silicide 103) and form a metal silicon nitride film 108 that is substantially free of silicon nitride (SiN). In some embodiments, the metal film 104 is exposed to the ammonia plasma at a temperature in a range of from 600° C. to 850° C.

The plasma treatment may have any suitable pressure. In one or more embodiments, the device 100 is treated with an ammonia plasma at a pressure in a range of from 0.2 Torr to less than 5 Torr, or in a range of from 0.2 Torr to 4.5 Torr, or in a range of from 0.2 Torr to 3.5 Torr, or in a range of from 0.2 Torr to 2.5 Torr, or in a range of from 0.2 Torr to 1.5 Torr.

The plasma treatment may occur for any suitable period of time. In one or more embodiments, the device 100 is treated with an ammonia plasma for a period of time in a range of from 10 seconds to 10 minutes, or in a range of from 10 seconds to 5 minutes, or in a range of from 10 seconds to 4.5 min, or in a range of from 10 seconds to 3 minutes, or in a range of from 10 seconds to 2 minutes, or in a range of from 30 sec to 2 minutes.

Without intending to be bound by theory, it is thought that the nitrogen atom, N, of the NH* radicals 106 from the ammonia plasma will only bond to the metal of the metal film 104 or the metal of the metal silicide 103, such that silicon nitride (SiN) cannot form. As used herein, the phrase “silicon nitride (SiN) cannot form” means that NH* will not react with silicon (Si)—the bulk or substrate silicon layer—and form a silicon nitride (SiN) layer, which would be under the metal silicide layer and at the interface of the metal silicide and silicon substrate. Without intending to be bound by theory, there is a possibility that N from NH* could bond on one side with Ti and on the other side with Si in TiSI layer and forming Ti—N—Si bonding in addition to N from NH* bonding with Ti only. In one or more embodiments, N from NH* will not bond with Si in all Si—Si bonding environments such as the Si substrate.

Accordingly, the metal silicon nitride film 108 is substantially free of silicon nitride (SiN). As used herein, the term “substantially free” means that there is less than 5%, including less than 4%, less than 3%, less than 2%, less than 1%, and less than 0.5% of silicon nitride (SiN) in the metal silicon nitride film 108.

In one or more embodiments, the metal silicon nitride film 108 is selected from titanium silicon nitride (TiSiN), cobalt silicon nitride (CoSiN), molybdenum silicon nitride (MoSiN), ruthenium silicon nitride (RuSiN), tungsten silicon nitride (WSiN), nickel silicon nitride (NiSiN), and the like. In one or more embodiments, the metal silicon nitride film 108 is substantially free of silicon nitride (SiN).

In one or more embodiments, the metal silicon nitride film 108, is a titanium silicon nitride (TiSiN) film and comprises less than 10% silicon nitride (SiN) by weight. In other embodiments, the titanium silicon nitride (TiSiN) film comprises less than 5% silicon nitride (SiN) by weight. And in still further embodiments, the titanium silicon nitride (TiSiN) film comprises less than 1% silicon nitride (SiN) by weight.

In some embodiments, the metal silicon nitride films 108 of this disclosure have lower resistivity. In some embodiments, the resistivity of a metal silicon nitride film 108, e.g., titanium silicon nitride (TiSiN) film, is less than or equal to 200 μΩ·cm, less than or equal to 180 μΩ·cm, less than or equal to 160 μΩ·cm, less than or equal to 150 μΩ·cm, or less than or equal to 140 μΩ·cm. In some embodiments, the metal silicon nitride films of this disclosure have a lower resistivity than a metal silicon nitride film deposited by a plasma process with a nitrogen plasma exposure. In some embodiments, the metal silicon nitride films of this disclosure have a lower resistivity than a metal silicon nitride film deposited by a thermal process.

The metal silicon nitride film 108 may have any suitable thickness. In one or more embodiments, the metal silicon nitride film 108 has a thickness in a range of from 0.5 nm to 15 nm, or in a range of from 1 nm to 10 nm, or in a range of from 2 nm to 6 nm.

At operation 16, the method 10 can either end or proceed for optional further processing (e.g., bulk deposition of a metal film, anneal).

In one or more embodiments, the metal silicon nitride film 108 is a portion of DRAM bit line contact. As used herein, the term “bit line” refers to a layer(s) of material that is an electrical conductor. The bit line contact is the connection between the bit line and the silicon where the metal silicide film is formed.

In such embodiments, the substrate 102 may comprise silicon (Si), and the metal film 104 may comprise titanium (Ti) or titanium nitride (TiN). Accordingly, the metal silicide 103 is titanium silicide (TiSi). When the titanium silicide is treated with ammonia plasma, a titanium silicon nitride (TiSiN) that is substantially free of silicon nitride (SiN) forms.

In one or more embodiments, a plasma processing apparatus is used to generate the plasma and treat the metal film with ammonia plasma. In one or more embodiments, the plasma processing apparatus is a stand-alone tool and is not part of a cluster tool. In other embodiments, the plasma processing apparatus is part of a cluster tool.

Several well-known cluster tools which may be adapted for the present disclosure are the Olympia®, the Continuum®, and the Trillium®, all available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), plasma treatment, etch, pre-clean, chemical clean, thermal treatment such as RTP, plasma nitridation, degas, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrates are individually loaded into a first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

One or more embodiments provide a non-transitory computer readable medium including instructions, that, when executed by a controller of a processing chamber, causes the processing chamber to perform the operations of: expose a substrate to a metal precursor and a reactant to form a metal film on the substrate, the substrate comprising a metal silicide; and expose the metal film to a plasma comprising ammonia (NH₃) at a temperature in a range of from 450° C. to 1000° C. to form NH radicals that diffuse through the metal film and form a metal silicon nitride film that is substantially free of silicon nitride (SiN).

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A method of forming a semiconductor device, the method comprising:
exposing a metal silicide film to a plasma comprising ammonia (NH₃) at a temperature in a range of from 450° C. to 1000° C. to form NH radicals that diffuse through the metal silicide film and form a metal silicon nitride film that is substantially free of silicon nitride (SiN).

2. The method of claim 1, wherein the plasma further comprises an inert gas selected from argon (Ar), helium (He), and xenon (Xe).

3. The method of claim 2, wherein the ammonia (NH₃) and the inert gas are in a ratio of 1:1000 to 1:5.

4. The method of claim 1, wherein the plasma has a pressure in a range of from 0.2 Torr to 5 Torr.

5. The method of claim 1, wherein the metal silicon nitride film comprises less than 10% silicon nitride (SiN) by weight.

6. The method of claim 1, wherein the plasma is a remote plasma.

7. The method of claim 1, wherein the metal silicide film is exposed to the plasma at a temperature in a range of from 600° C. to 850° C.

8. The method of claim 1, wherein the metal silicide film comprises a metal selected from titanium (Ti), cobalt (Co), molybdenum (Mo), ruthenium (Ru), tungsten (W), and nickel (Ni).

9. The method of claim 1, wherein the metal silicide film is selected from titanium silicide (TiSi), cobalt silicide (CoSi), molybdenum silicide (MoSi), ruthenium silicide (RuSi), tungsten silicide (WSi), and nickel silicide (NiSi).

10. The method of claim 1, wherein the metal silicon nitride film is selected from titanium silicon nitride (TiSiN), cobalt silicon nitride (CoSiN), molybdenum silicon nitride (MoSiN), ruthenium silicon nitride (RuSiN), tungsten silicon nitride (WSiN), and nickel silicon nitride (NiSiN).

11. The method of claim 1, wherein the metal silicide film has a thickness in a range of from 2 nm to 6 nm.

12. The method of claim 1, wherein the metal silicide film comprises a metal film on a substrate, the metal film comprising one or more of titanium (Ti), cobalt (Co), molybdenum (Mo), ruthenium (Ru), tungsten (W), nickel (Ni), and titanium nitride (TiN), and the substrate selected from silicon (Si) or silicon germanium (SiGe).

13. The method of claim 1, wherein the metal silicide film is exposed to the plasma for a time period in a range of from 30 seconds to 2 minutes.

14. A method of forming a semiconductor device, the method comprising:
exposing a titanium film to a plasma comprising ammonia (NH₃) at a temperature in a range of from 450° C. to 1000° C. to form NH radicals that diffuse through the titanium film and form a titanium silicon nitride (TiSiN) film that is substantially free of silicon nitride (SiN).

15. The method of claim 13, wherein the titanium film is selected from titanium (Ti), titanium/titanium nitride (Ti/TiN), and titanium silicide (TiS).

16. The method of claim 13, wherein the titanium silicon nitride (TiSiN) film comprises less than 10% silicon nitride (SiN) by weight.

17. The method of claim 13, wherein the titanium film is exposed to the plasma at a temperature in a range of from 600° C. to 850° C.

18. The method of claim 13, wherein the titanium film is exposed to the plasma for a time period in a range of from 30 seconds to 2 minutes.

19. The method of claim 13, wherein the plasma is flowed with an inert gas in a ratio of ammonia to inert gas of 1:100 to 1:5, and wherein the plasma has a pressure in a range of from 0.2 Torr to 5 Torr.

20. A non-transitory computer readable medium including instructions, that, when executed by a controller of a processing chamber, causes the processing chamber to perform the operations of:
expose a metal silicide film to a plasma comprising ammonia (NH₃) at a temperature in a range of from 450° C. to 1000° C. to form NH radicals that diffuse through the metal silicide film and form a metal silicon nitride film that is substantially free of silicon nitride (SiN).
